(19) United States
(12) Patent Application Publication
(10) Pub. No.: US 2009/0108291 A1
(43) Pub. Date: Apr. 30, 2009

(54) SEMICONDUCTOR DEVICE AND METHOD FOR FABRICATING THE SAME

(75) Inventors: Po-Lun Cheng, Kaohsiung County (TW); Pin-Chien Chu, Kaohsiung County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/925,328

(22) Filed: Oct. 26, 2007

(51) Int. Cl. H01L 29/778; H01L 21/336

(52) U.S. Cl. 257/190; 438/285; 257/E21.403; 257/E29.246

(57) ABSTRACT

A semiconductor device including a gate structure, two doped regions, and two buffer layers is provided. The gate structure is disposed on a substrate. The two doped regions are made of boron doped silicon germanium (SiGeB) and are disposed in the substrate at both sides of the gate structure. The two buffer layers are made of carbon doped silicon germanium (SiGeC) and are respectively disposed between the two doped regions and the substrate.

### BACKGROUND OF THE INVENTION

1. Field of the Invention

The present invention generally relates to an integrated circuit (IC) and a fabrication method thereof, in particular, to a semiconductor device and a fabrication method thereof.

2. Description of Related Art

Metal oxide semiconductor (MOS) is a most common element used in many different semiconductor devices, such as memories, image sensors, or displays. A typical MOS includes a silicon oxide dielectric layer, a gate conductive layer, and a heavily doped source/drain contact region. Along with the decrease in the linewidth of semiconductor device, the size thereof is reduced, and due to the reduction in the gate width of a typical MOS, the channel length of the MOS is also reduced. Short channel effect may be induced in a MOS because the threshold voltage thereof is reduced and the sub-threshold current thereof is increased. On the other hand, after the gate width is reduced, hot carrier effect may be caused due to the increase in the electric field between the source and the drain. Thereby, many carriers may be generated in the channel close to the drain and accordingly electrical breakdown effect may be caused. A sufficient channel length has to be maintained to avoid the breakdown effect, which causes the MOS to be unusable.

One of the methods for resolving foregoing problem is to adopt a lightly doped drain (LDD). According to this method, the dopant concentration of the source/drain close to the channel is reduced to form the LDD and accordingly to reduce the hot carrier effect caused by increment of the electric field between the source and the drain. However, since the dopant concentration of the LDD is reduced, the resistance thereof is increased and which causes the electron mobility in the channel region and the operation speed of the MOS to decrease and the power consumption of the MOS to increase.

The operation speed of a MOS can be increased by changing the mobility of electrons and holes in the channel through the control over the mechanical stress in the channel. A conventional technique for fabricating the source/drain contact region of a transistor with silicon germanium (SiGe) epitaxy has been provided. Compared to the characteristics of silicon materials, germanium has larger atom volume and can apply a compression stress to the channel, thus, the mobility of holes can be increased, and accordingly, the performance of the transistor can be improved, by forming the source/drain contact regions with SiGe.

The boron dopant in the doped region of a PMOS may diffuse outwards, and accordingly electrical problems may be incurred to the PMOS. According to a conventional technique for resolving the problem of boron diffusion, an undoped SiGe buffer layer is disposed between the doped region and the substrate. However, a very thick layer of undoped SiGe layer has to be disposed to prevent boron diffusion since boron may still diffuse into the channel region in the undoped SiGe. Because the resistance of undoped SiGe is very high, the thicker the undoped SiGe buffer layer is, the more it affects the resistance of the doped region and the worse the performance of the PMOS is.

### SUMMARY OF THE INVENTION

Accordingly, the present invention is directed to a semiconductor device which can prevent boron diffusion effectively.

The present invention is directed to a semiconductor device, wherein boron diffusion is prevented with very thin buffer layers so that the semiconductor device is prevented from producing any electrical problem.

The present invention is directed to a method for fabricating a semiconductor device, wherein buffer layers which can effectively prevent boron diffusion are formed through a very simple process.

The present invention provides a semiconductor device including a gate structure, two doped regions, and two buffer layers. The gate structure is disposed on a substrate. The doped regions are made of boron doped silicon germanium (SiGeB) and are disposed in the substrate at both sides of the gate structure. The buffer layers are made of carbon doped silicon germanium (SiGeC) and are respectively disposed between the doped regions and the substrate.

According to an embodiment of the present invention, in the semiconductor device, the doped regions are further doped with carbon.

According to an embodiment of the present invention, in the semiconductor device, the buffer layers are further doped with boron, and the concentration of boron in the buffer layers is lower than that in the doped regions.

According to an embodiment of the present invention, in the semiconductor device, the doped regions are further doped with carbon.

According to an embodiment of the present invention, in the semiconductor device, the concentration of carbon in the buffer layers is between 0.05% and 1%.

According to an embodiment of the present invention, in the semiconductor device, the material of the substrate is different from the material of the doped regions or different from the material of the buffer layers.

According to an embodiment of the present invention, in the semiconductor device, the buffer layers respectively surround the doped regions.

According to an embodiment of the present invention, in the semiconductor device, the doped regions are source/drain contact regions.

According to an embodiment of the present invention, the semiconductor device further includes two source/drain extension regions disposed in the substrate between the buffer layers.

The present invention provides a method for fabricating a semiconductor device. The method includes following steps. First, a gate structure is formed on a substrate. Next, a recess is respectively formed in the substrate at each side of the gate structure. After that, a buffer layer and a first doped region are formed in each recess, wherein the buffer layer is disposed between the substrate and the first doped region, the material of the buffer layers includes SiGeC, and the material of the first doped regions includes SiGeB.

According to an embodiment of the present invention, in the semiconductor device fabrication method, a first reactive gas used for forming the buffer layers includes at least a carbon dopant source, a silicon source, and a germanium source.

According to an embodiment of the present invention, in the semiconductor device fabrication method, the carbon dopant source includes alkyl silane, the silicon source includes alkyl-free silane or halogenosilane, and the germanium source includes germane.

According to an embodiment of the present invention, in the semiconductor device fabrication method, the alkyl silane includes methylsilane, the alkyl-free silane or halogenosilane includes silicomethane (SiH₄) or diclorosilane (SiH₂Cl₂).

According to an embodiment of the present invention, in the semiconductor device fabrication method, the first reactive gas further includes borane for doping boron into the buffer layers, wherein the concentration of boron in the buffer layers is lower than that in the first doped regions.

According to an embodiment of the present invention, in the semiconductor device fabrication method, a second reactive gas used for forming the first doped regions includes at least a silicon source, a germanium source, and a boron dopant source.

According to an embodiment of the present invention, in the semiconductor device fabrication method, the silicon source in the second reactive gas includes alkyl-free silane or halogenosilane, the germanium source includes germane, and the boron dopant source includes borane.

According to an embodiment of the present invention, in the semiconductor device fabrication method, the alkyl-free silane or halogenosilane in the second reactive gas includes silicomethane or diclorosilane.

According to an embodiment of the present invention, in the semiconductor device fabrication method, the second reactive gas further includes alkyl silane for doping carbon into the doped regions.

According to an embodiment of the present invention, in the semiconductor device fabrication method, a third reactive gas used for forming the first doped regions includes a silicon source, a germanium source, and a boron dopant source.

According to an embodiment of the present invention, in the semiconductor device fabrication method, the silicon source in the third reactive gas includes alkyl-free silane or halogenosilane, the germanium source includes germane, and the boron dopant source includes borane.

According to an embodiment of the present invention, in the semiconductor device fabrication method, the alkyl-free silane or halogenosilane in the third reactive gas includes silicomethane or diclorosilane.

According to an embodiment of the present invention, in the semiconductor device fabrication method, the third reactive gas further includes alkyl silane for doping carbon into the doped regions.

According to an embodiment of the present invention, in the semiconductor device fabrication method, the concentration of carbon in the buffer layers is between 0.05% and 1%.

According to embodiments of the present invention, boron diffusion can be effectively prevented in the semiconductor device.

According to embodiments of the present invention, boron diffusion can be effectively prevented by disposing only very thin buffer layers in the semiconductor device, so that the semiconductor device is prevented from producing any electrical problem.

According to embodiments of the present invention, in the method for fabricating the semiconductor device, the buffer layers which can effectively prevent boron diffusion are formed through a simple process.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a semiconductor device according to an embodiment of the present invention.

FIGS. 2A˜2D are cross-sectional views illustrating a fabrication method of a semiconductor device according to an embodiment of the present invention.

FIGS. 3A˜3D are cross-sectional views illustrating a fabrication method of a semiconductor device according to another embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

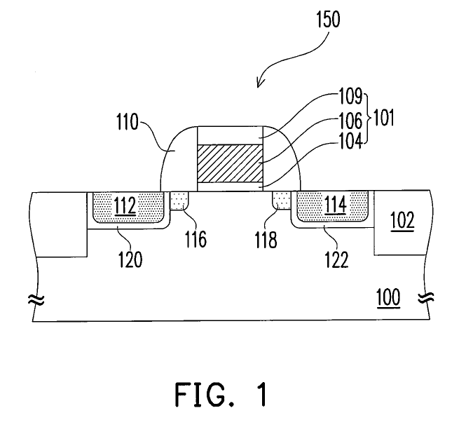

FIG. 1 is a cross-sectional view of a semiconductor device according to an embodiment of the present invention.

Referring to FIG. 1, the semiconductor device 150 in the present embodiment may be a metal oxide semiconductor (MOS) device. The semiconductor device 150 includes a substrate 100, a gate structure 101, doped regions 112 and 114, and buffer layers 120 and 122. The material of the substrate 100 may be a semiconductor (for example, silicon) or a semiconductor compound, or the substrate 100 may also be a silicon on insulator (SOI) substrate. In an embodiment of the present invention, the substrate 100 is N-type doped silicon or P-type doped silicon having N-well. The gate structure 101 is disposed on an active region defined by an isolation structure 102. When the semiconductor device 150 is a metal oxide semiconductor (MOS) device, the gate structure 101 includes a patterned gate dielectric layer 104 and a patterned gate conductive layer 106. The material of the gate dielectric layer 104 may be silicon nitride, silicon-oxy-nitride, or a material having high dielectric constant. The gate conductive layer 106 is made of a material containing mostly silicon, such as doped silicon, undoped silicon, doped polysilicon, or undoped polysilicon. When the gate conductive layer 106 is made of doped silicon or doped polysilicon, the dopants thereof may be N-dopants or P-dopants.

The gate structure 101 may further include a patterned material layer 109 disposed on the patterned gate conductive layer 106. The patterned material layer 109 may be a metal silicide layer or a cap layer. The metal silicide layer may be a silicide layer of a refractory metal, such as Ni, Co, Ti, Cu, Mo, Ta, W, Er, Zr, Pt, or an alloy of foregoing metals. The material of the cap layer may be a dielectric material, such as silicon oxide or silicon nitride. A spacer 110 may be further disposed on the sidewall of the gate structure 101. The spacer 110 may be a single-layer spacer or a multilayer spacer, and the material of the spacer 110 may be a dielectric material, such as silicon oxide or silicon nitride.

The doped regions 112 and 114 are disposed in the substrate 100 at both sides of the gate structure 101 or are extended upwards and protruded from the surface of the substrate 100. The material of the doped regions 112 and 114 is different from the material of the substrate 100, and which includes an N-doped semiconductor compound, such as boron doped silicon germanium (SiGeB). In an embodiment of the present invention, the material of the doped regions 112 and 114 is SiGeB containing no carbon dopant. In another embodiment of the present invention, the material of the doped regions 112 and 114 is SiGeB containing carbon dopant. The semiconductor device 150 may include a metal silicide layer 130 on the doped regions 112 and 114 for reducing the resistance of the doped regions 112 and 114. The metal silicide layer 130 may be a silicide layer of a refractory metal, such as Ni, Co, Ti, Cu, Mo, Ta, W, Er, Zr, Pt, or an alloy of foregoing metals. In an embodiment of the present invention, the semiconductor device 150 is a MOS device, and the doped regions 112 and 114 may be source/drain contact regions. When the doped regions 112 and 114 are source/drain contact regions, the MOS device may further includes another two doped regions 116 and 118, also referred as source/drain extension regions, disposed below the spacer 110 and between the doped regions 112 and 114. The doped regions 116 and 118 may be made of the same or a different material as the substrate 100. In an embodiment of the present invention, the material of the doped regions 116 and 118 is the same as that of the substrate 100, such as P-doped silicon, wherein the P-type dopant may be boron. The dopant concentration of the doped regions 116 and 118 may be the same as or lower than that of the doped regions 112 and 114.

The buffer layers 120 and 122 are respectively disposed between the doped regions 112 and 114 and the substrate 100 for preventing the dopant in the doped regions 112 and 114 from diffusing outwards into a channel region. In an embodiment of the present invention, the buffer layers 120 and 122 are respectively disposed between the doped regions 112 and 114 and the doped regions 116 and 118, and the buffer layers 120 and 122 respectively surround the doped regions 112 and 114. The material of the buffer layers 120 and 122 is different from that of the substrate 100, and which may be a carbon doped semiconductor compound such as carbon doped silicon germanium (SiGeC). In an embodiment of the present invention, the concentration of carbon in the buffer layers 120 and 122 is between 0.05% and 1%. In an embodiment of the present invention, the material of the buffer layers 120 and 122 is SiGeC containing no dopant of the doped regions 112 and 114. In another embodiment of the present invention, the material of the buffer layers 120 and 122 is SiGeC containing dopant of the doped regions 112 and 114, such as boron, but the dopant concentration of the buffer layers 120 and 122 is lower than that of the doped regions 112 and 114. The boron in the buffer layers 120 and 122 may be doped through in-situ doping or from the doped regions 112 and 114 or the doped regions 116 and 118. In an embodiment of the present invention, the boron in the doped regions 112 and 114 diffuses outwards into the buffer layers 120 and 122 and further diffuses outwards into the substrate 100 outside of the buffer layers 120 and 122 during thermal cycles. However, because the material of the buffer layers 120 and 122 contains carbon, it traps the dopant in the doped regions 112 and 114 and prevents the dopant from diffusing outwards into the channel region effectively. Accordingly, the buffer layers 120 and 122 can be very thin. For example, the buffer layers 120 and 122 can prevent the dopant in the doped regions 112 and 114 from diffusing outwards into the channel region with a thickness of only 20A˜150A. The buffer layers 120 and 122 hardly affect the resistance of the semiconductor device because of the small thickness thereof.

The semiconductor device described above can be fabricated differently. Embodiments of the present invention for fabricating foregoing semiconductor device will be described below; however, these embodiments are not intended for restricting the scope of the present invention.

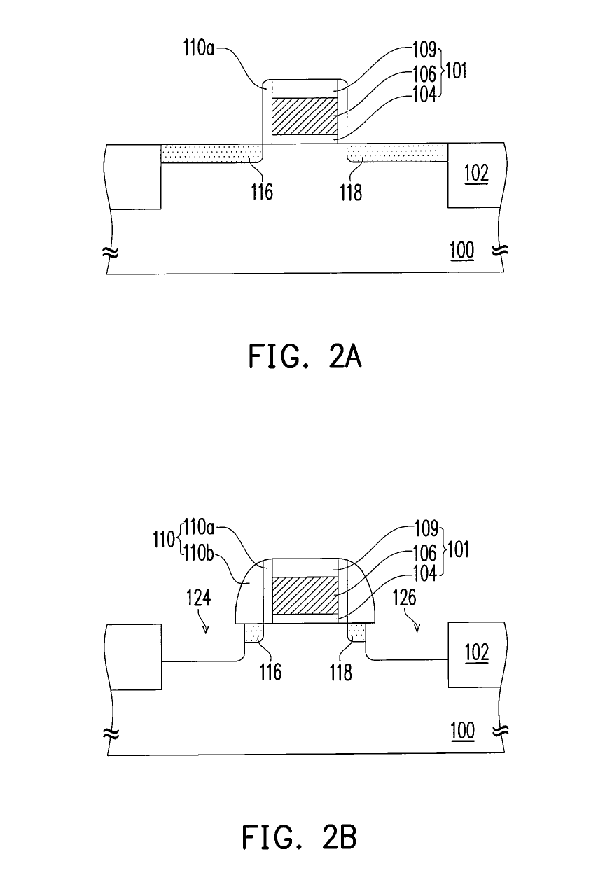

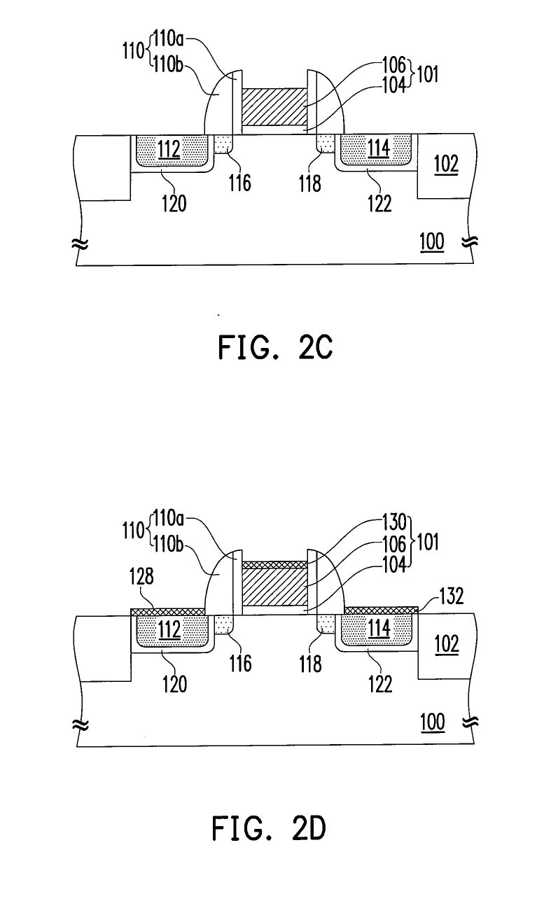

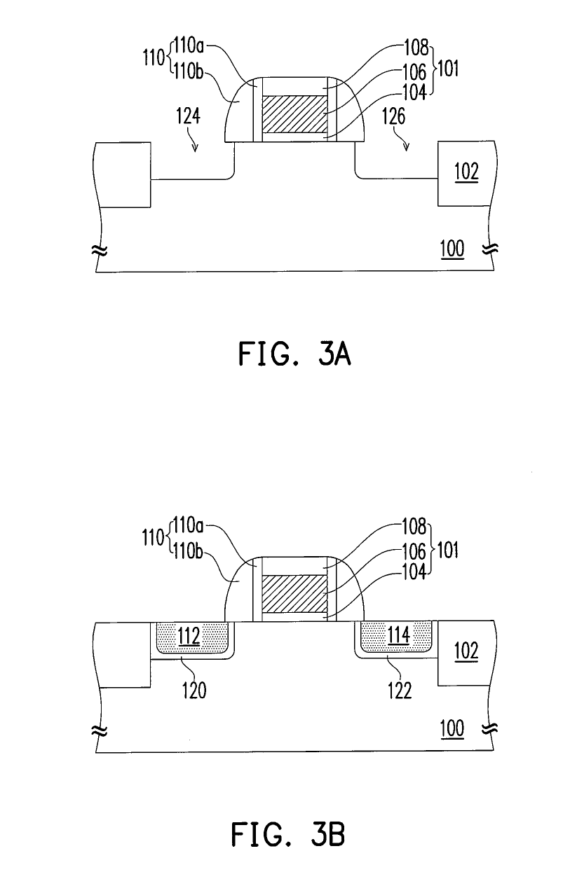

FIGS. 2A˜2D are cross-sectional views illustrating a fabrication method of a semiconductor device according to an embodiment of the present invention.

Referring to FIG. 2A, a substrate 100 is provided. The material of the substrate 100 may be a semiconductor (for example, silicon) or a semiconductor compound, or the substrate 100 may also be a SOI substrate. In an embodiment of the present invention, the substrate 100 may be N-doped silicon or P-doped silicon having N-well. Next, an isolation structure 102 is formed in the substrate 100. The isolation structure 102 may be formed through shallow trench isolation (STI).

Thereafter, a gate structure 101 is formed on the substrate 100. When the semiconductor device is a MOS device, the gate structure 101 includes a patterned gate dielectric layer 104, a patterned gate conductive layer 106, and a patterned cap layer 108. The material of the gate dielectric layer 104 may be silicon nitride, silicon-oxy-nitride, or a material having high dielectric constant, and the gate dielectric layer 104 may be formed through thermal oxidation or chemical vapor deposition (CVD). When the material of the gate conductive layer 106 is doped silicon or doped polysilicon, the dopants thereof may be N-dopants or P-dopants. The material of the cap layer 108 may be silicon oxide, and the formation method thereof may be CVD. Next, an off-set spacer 110a is formed on the sidewall of the gate structure 101. The material of the off-set spacer 110a may be silicon oxide, and the formation method thereof may be thermal oxidation.

After that, two doped regions 116 and 118, such as source/drain extension regions, are formed in the substrate 100 at both sides of the gate structure 101. The doped regions 116 and 118 may be P-doped (for example, doped with boron). The doped regions 116 and 118 may be formed through ion implantation.

Thereafter, referring to FIG. 2B, a spacer 110b is formed on the off-set spacer 110a on the sidewall of the gate structure 101 so as to form a spacer 110 with the off-set spacer 110a and spacer 110b. The material of the spacer 110b may be a dielectric material, such as silicon oxide or silicon nitride. The shape and number of layers of the spacer 110 are not limited to those illustrated in the figure; instead, the spacer 110 may also be other shapes or have more layers.

Thereafter, an etching process is performed to the substrate 100 at both sides of the gate structure 101 with the cap layer 108 and the spacer 110 as a mask, so as to form recesses 124 and 126. The etching process may be an anisotropic etching process or an isotropic etching process. The anisotropic etching process includes a dry etching process. In an embodiment of the present invention, the dry etching process may be a plasma etching process, and the reactive gas used is fluoro-hydrocarbons, such as CF₄ and CHF₃. The isotropic etching process may be a dry etching process or a wet etching process. In an embodiment of the present invention, the dry etching process is a plasma etching process, and the reactive gas used includes NF₃, O₂, and Cl₂. The wet etching process may use a buffered oxide etchant (BOE) as its etchant.

Next, referring to FIG. 2C, two buffer layers 120 and 122 are formed in the recesses 124 and 126, respectively. The material of the buffer layers 120 and 122 is different from the material of the substrate 100, and which may be a carbon doped semiconductor compound such as SiGeC, wherein the concentration of carbon is between 0.05% and 1%. In an embodiment of the present invention, the material of the buffer layers 120 and 122 is SiGeC containing no boron dopant. The buffer layers 120 and 122 may be formed by performing a selective area epitaxy growth process of silicon and in-situ doping carbon through CVD, so as to form a SiGeC epitaxy layer. The carbon dopant source used in the in-situ doping may be alkyl silane. The reactive gas used for forming the SiGeC epitaxy layer includes a carbon dopant source, a silicon source, and a germanium source. For example, the carbon dopant source is alkyl silane, the silicon source is alkyl-free silane or halogenosilane, and the germanium source is germane. The alkyl silane may be methylsilane, while the alkyl-free silane or halogenosilane may be silicomethane or dichlorosilane respectively. In an embodiment of the present invention, the reactive gas used includes methylsilane, dichlorosilan, germane, and hydrogen chloride, and the flow rate thereof are respectively 5˜40 sccm, 50˜200 sccm, 10˜100 sccm, and 10˜200 sccm, the temperature is 600˜800° C., and the pressure is 5˜50 torr. In another embodiment of the present invention, the material of the buffer layers 120 and 122 is SiGeC containing boron of very small quantity. The boron may be doped through in-situ doping during the epitaxy growth process for forming the SiGeC or may result from the diffusion of boron dopants in the doped regions 116 and 118 or the doped regions 112 and 114 formed subsequently.

Next, two doped regions 112 and 114 are formed after the buffer layers 120 and 122 are formed, wherein the doped regions 112 and 114 may be source/drain contact regions. The material of the doped regions 112 and 114 is different from the material of the substrate 100 and which may be a P-doped semiconductor compound such as SiGeB. In an embodiment of the present invention, the material of the doped regions 112 and 114 is SiGeB containing no carbon. The doped regions 112 and 114 may be formed by performing a selective area epitaxy growth process of silicon and in-situ doping boron through CVD, or by performing a selective area epitaxy growth process of silicon to form a SiGe epitaxy layer first and then doping boron through ion implantation, so as to form a SiGeB epitaxy layer. The reactive gas used for forming the SiGeB epitaxy layer includes a silicon source, a germanium source, and a boron dopant source. The silicon source may be alkyl-free silane or halogenosilane, the germanium source may be germane, and the boron dopant source may be borane. The alkyl-free silane or halogenosilane may be silicomethane or halogenated silane such as dichlorosilane. In an embodiment of the present invention, the reactive gas used includes dichlorosilane, germane, hydrogen chloride, and borane, and the flow rate thereof are respectively 50˜200 sccm, 10˜100 sccm, 10˜200 sccm, and 50˜300 sccm, wherein the temperature of the reactive gas is 600˜800° C., and the pressure thereof is 5˜50 torr. In another embodiment of the present invention, the material of the doped regions 112 and 114 is SiGeB containing carbon. The concentration of carbon in the doped regions 112 and 114 is between 0.05˜1%. The doped regions 112 and 114 may be formed by performing a selective area epitaxy growth process of silicon and in-situ doping boron and carbon through CVD, or by performing a selective area epitaxy growth process of silicon and in-situ doping carbon through CVD to form a SiGeC epitaxy layer first and then doping boron through ion implantation to form a boron and carbon doped SiGe epitaxy layer. The reactive gas used for forming the boron and carbon doped SiGe epitaxy layer includes carbon dopant source, silicon source, germanium source, and boron dopant source. The carbon dopant source maybe alkyl silane, the silicon source may be alkyl-free silane or halogenosilane, and the germanium source may be germane, and the boron dopant source may be borane. The alkyl silane may be methylsilane, the alkyl-free silane or halogenosilane may be silicomethane or dichlorosilane. In an embodiment of the present invention, the reactive gas used includes methylsilane, dichlorosilane, germane, hydrogen chloride, and borane, and the flow rate thereof are respectively 5˜40 sccm, 50˜200 sccm, 10˜100 sccm, 10˜200 sccm, and 50˜300 sccm, wherein the temperature is 600˜800° C., and the pressure is 5˜50 torr.

After that, the cap layer 108 is removed. The cap layer 108 may be removed through wet etching, for example, by using a diluted hydrofluoric acid solution.

Next, referring to FIG. 2D, metal silicide layers 128, 132, and 130 are respectively formed on the doped regions 112 and 114 and the gate conductive layer 106 for reducing the resistances thereof. The metal silicide layers 128, 132, and 130 may be formed through a self-aligned silicide process. The metal used in the metal silicide layers may be a refractory metal, such as Ni, Co, Ti, Cu, Mo, Ta, W, Er, Zr, Pt, or an alloy of foregoing metals.

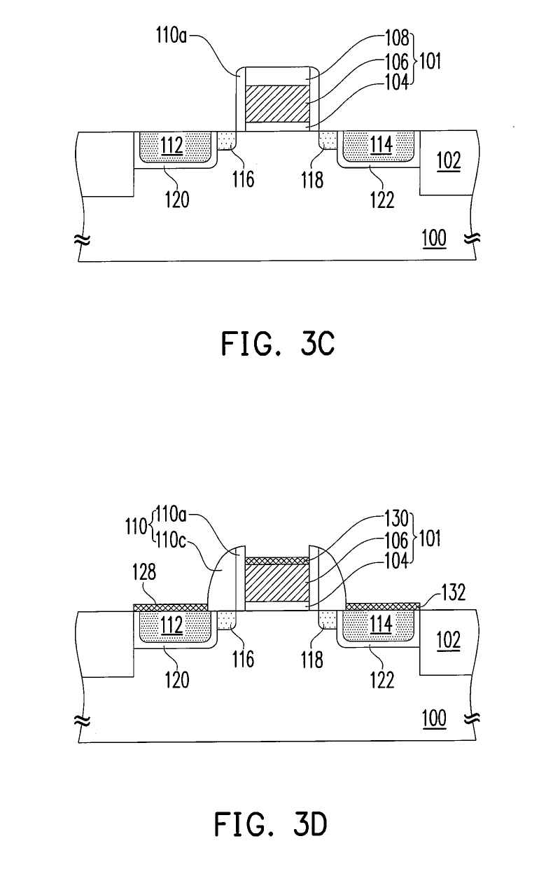

FIGS. 3A˜3D are cross-sectional views illustrating a fabrication method of a semiconductor device according to another embodiment of the present invention.

Referring to FIG. 3A, a substrate 100 is provided. The material of the substrate 100 may be a semiconductor (for example, silicon) or a semiconductor compound, or the substrate 100 may also be a SOI substrate. In an embodiment of the present invention, the material of the substrate 100 is N-doped silicon or P-doped silicon having N-well. Next, an isolation structure 102 is formed in the substrate 100. The isolation structure 102 may be formed through STI.

After that, a gate structure 101 is formed on the substrate 100. When the semiconductor device is a MOS device, the gate structure 101 includes a patterned gate dielectric layer 104, a patterned gate conductive layer 106, and a patterned cap layer 108. The material of the gate dielectric layer 104 may be silicon nitride, silicon-oxy-nitride, or a material having high dielectric constant, and the gate dielectric layer 104 may be formed through thermal oxidation or CVD. When the material of the gate conductive layer 106 is doped silicon or doped polysilicon, the dopants thereof may be N-dopants or P-dopants. The material of the cap layer 108 may be silicon oxide, and the formation method thereof may be CVD. Next, an off-set spacer 110a is formed on the sidewall of the gate structure 101. The material of the off-set spacer 110a may be silicon oxide, and the formation method thereof may be thermal oxidation. A spacer 110b is formed on the off-set spacer 110a on the sidewall of the gate structure 101 so as to form a spacer 110 with the off-set spacer 110a and the spacer 110b. The material of the spacer 110b may be a dielectric material, such as silicon oxide or silicon nitride. The spacer 110b may be formed by forming a dielectric material layer first and then performing an anisotropic etching process to the dielectric material layer. The shape and number of layers of the spacer 110 are not limited to those illustrated in the figure; instead, the spacer 100 may also be other shapes or have more layers.

Thereafter, an etching process is performed to the substrate 100 at both sides of the gate structure 101 with the cap layer 108 and the spacer 110 as a mask, so as to form recesses 124 and 126. The etching process may be an anisotropic etching process or an isotropic etching process. The anisotropic etching process includes a dry etching process. In an embodiment of the present invention, the dry etching process may be a plasma etching process, and the reactive gas used is fluorohydrocarbon, such as CF₄ and CHF₃. The isotropic etching process may be a dry etching process or a wet etching process. In an embodiment of the present invention, the dry etching process is a plasma etching process, and the reactive gas used includes NF₃, O₂, and Cl₂. The wet etching process may use a BOE as its etchant.

After that, referring to FIG. 3B, buffer layers 120 and 122 are formed in the recesses 124 and 126, respectively. The material of the buffer layers 120 and 122 is different from the material of the substrate 100, and which may be a carbon doped semiconductor compound, such as SiGeC, wherein the concentration of carbon in the buffer layers 120 and 122 is between 0.05% and 1%. In an embodiment of the present invention, the material of the buffer layers 120 and 122 is SiGeC containing no boron. The buffer layers 120 and 122 may be formed by performing a selective area epitaxy growth process of silicon and in-situ doping carbon through CVD, so as to form a SiGeC epitaxy layer. The reactive gas used for forming the SiGeC epitaxy layer includes a carbon dopant source, a silicon source, and a germanium source. The carbon dopant source may be alkyl silane, the silicon source may be alkyl-free silane or halogenosilane, and the germanium source may be germane. The alkyl silane may be methylsilane, and the alkyl-free silane or halogenosilane may be silicomethane or dichlorosilane. In an embodiment of the present invention, the reactive gas used includes methylsilane, dichlorosilane, germane, and hydrogen chloride, and the flow rate thereof are respectively 5˜40 sccm, 50˜200 sccm, 10˜100 sccm, and 10˜200 sccm, wherein the temperature is 600˜800° C., and the pressure is 5˜50 torr. In another embodiment of the present invention, the material of the buffer layers 120 and 122 is SiGeC containing boron of very small quantity. The boron may be doped through in-situ doping during the epitaxy growth process for forming the SiGeC or may result from the diffusion of boron dopants in the doped regions 116 and 118 or the doped regions 112 and 114 formed subsequently.

Next, two doped regions 112 and 114 are formed after the buffer layers 120 and 122 are formed, wherein the doped regions 112 and 114 may be source/drain contact regions. The material of the doped regions 112 and 114 is different from the material of the substrate 100, and which may be a P-doped semiconductor compound, such as SiGeB. In an embodiment of the present invention, the material of the doped regions 112 and 114 is SiGeB containing no carbon. The doped regions 112 and 114 may be formed by performing a selective area epitaxy growth process of silicon and in-situ doping boron through CVD, or by performing a selective area epitaxy growth process of silicon to form a SiGe epitaxy layer first and then doping boron through ion implantation, so as to form a SiGeB epitaxy layer. The reactive gas used for forming the SiGeB epitaxy layer includes a silicon source, a germanium source, and a boron dopant source. The silicon source may be alkyl-free silane or halogenosilane, the germanium source may be germane, and the boron dopant source may be borane. The alkyl-free silane or halogenosilane may be silicomethane or dichlorosilane. In an embodiment of the present invention, the reactive gas used includes dichlorosilane, germane, hydrogen chloride, and borane, and the flow rate thereof are respectively 50˜200 sccm, 10˜100 sccm, 10˜200 sccm, and 50˜300 sccm, the temperature is 600˜800° C., and the pressure is 5˜50 torr. In another embodiment of the present invention, the material of the doped regions 112 and 114 is boron and carbon doped SiGe. The doped regions 112 and 114 may be formed by performing a selective area epitaxy growth process of silicon and in-situ doping boron and carbon through CVD, or by performing a selective area epitaxy growth process of silicon and in-situ doping carbon through CVD to form a SiGeC epitaxy layer and then doping boron through ion implantation, so as to form a boron and carbon doped SiGe epitaxy layer. The reactive gas used for forming the in-situ boron and carbon doped SiGe epitaxy layer includes a carbon dopant source, a silicon source, a germanium source, and a boron dopant source. The carbon dopant source may be alkyl silane, the silicon source may be alkyl-free silane or halogenosilane, the germanium source may be germane, and the boron dopant source may be borane. The alkyl silane may be methylsilane, and the alkyl-free silane or halogenosilane may be silicomethane or dichlorosilane. In an embodiment of the present invention, the reactive gas used includes methylsilane, dichlorosilane, germane, hydrogen chloride, and borane, and the flow rate thereof are respectively 5˜40 sccm, 50˜200 sccm, 10˜100 sccm, 10˜200 sccm, and 50˜300 sccm, wherein the temperature is 600˜800° C., and the pressure is 5˜50 torr.

After that, referring to FIG. 3C, the spacer 110b is removed, and then doped regions 116 and 118 are formed in the substrate 100, wherein the doped regions 116 and 118 may be source/drain extension regions. The doped regions 116 and 118 may be P-doped (for example, doped with boron). The doped regions 116 and 118 may be formed through ion implantation.

Next, referring to FIG. 3D, another spacer 110c is formed on the off-set spacer 110a. The material of the spacer 110c may be a dielectric material such as silicon oxide or silicon nitride. The spacer 110c may be formed by forming a dielectric material layer first and then performing an anisotropic etching process to the dielectric material layer. Next, the cap layer 108 is removed. The cap layer 108 may be removed through wet etching, for example, by using a diluted hydrofluoric acid solution. After that, metal silicide layers 128, 132, and 130 are respectively formed on the doped regions 112 and 114 and the gate conductive layer 106 for reducing the resistances thereof. The metal silicide layers 128, 132, and 130 may be formed through a self-aligned silicide process. The metal used in the metal silicide layers may be a refractory metal, such as Ni, Co, Ti, Cu, Mo, Ta, W, Er, Zr, Pt, or an alloy of foregoing metals.

According to the embodiments described above, the buffer layers formed around the doped regions are doped with carbon which can block boron diffusion outwards, thus, the buffer layers are very thin and accordingly they hardly affect the resistance of the semiconductor device.

According to the embodiments described above, the method for forming the carbon doped buffer layers around the doped regions is very simple, therefore it will not affect the yield of the entire product fabrication process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor device, comprising:
a gate structure, disposed on a substrate;
two doped regions, disposed in the substrate at both sides of the gate structure, wherein the material of the doped regions comprises boron doped silicon germanium (SiGeB); and
two buffer layers, respectively disposed between the doped regions and the substrate, wherein the material of the buffer layers comprises carbon doped silicon germanium (SiGeC).

2. The semiconductor device according to claim 1, wherein the doped regions are further doped with carbon.

3. The semiconductor device according to claim 1, wherein the buffer layers are further doped with boron, and the concentration of boron in the buffer layers is lower than the concentration of boron in the doped regions.

4. The semiconductor device according to claim 3, wherein the doped regions are further doped with carbon.

5. The semiconductor device according to claim 1, wherein the concentration of carbon in the buffer layers is between 0.05% and 1%.

6. The semiconductor device according to claim 1, wherein the material of the substrate is different from the material of the doped regions or different from the material of the buffer layers.

7. The semiconductor device according to claim 1, wherein the buffer layers respectively surround the doped regions.

8. The semiconductor device according to claim 1, wherein the doped regions are source/drain contact regions.

9. The semiconductor device according to claim 8 further comprising two source/drain extension regions disposed in the substrate between the buffer layers.

10. A method for fabricating a semiconductor device, comprising:
forming a gate structure on a substrate;
respectively forming a recess in the substrate at each side of the gate structure; and
forming a buffer layer and a first doped region in each recess, wherein each buffer layer is disposed between the substrate and the first doped region, the material of the buffer layers comprises SiGeC, and the material of the first doped regions comprises SiGeB.

11. The fabrication method according to claim 10, wherein a first reactive gas used for forming the buffer layer comprises at least a carbon dopant source, a silicon source, and a germanium source.

12. The fabrication method according to claim 11, wherein the carbon dopant source comprises alkyl silane, the silicon source comprises alkyl-free silane or halogenosilane, and the germanium source comprises germane.

13. The fabrication method according to claim 12, wherein the alkyl silane comprises methylsilane, the alkyl-free silane or halogenosilane comprises silicomethane or dichlorosilan.

14. The fabrication method according to claim 11, wherein the first reactive gas further comprises borane for doping boron into the buffer layer, and the concentration of boron in the buffer layer is lower than the concentration of boron in the first doped regions.

15. The fabrication method according to claim 14, wherein a second reactive gas used for forming the first doped regions comprises at least a silicon source, a germanium source, and a boron dopant source.

16. The fabrication method according to claim 15, wherein the silicon source comprises alkyl-free silane or halogenosilane, the germanium source comprises germane, and the boron dopant source comprises borane.

17. The fabrication method according to claim 16, wherein the alkyl-free silane or halogenosilane comprises silicomethane or dichlorosilane.

18. The fabrication method according to claim 14, wherein the second reactive gas further comprises alkyl silane for doping carbon into the doped regions.

19. The fabrication method according to claim 10, wherein a third reactive gas used for forming the first doped regions comprises a silicon source, a germanium source, and a boron dopant source.

20. The fabrication method according to claim 10, wherein the silicon source comprises alkyl-free silane or halogenosilane, the germanium source comprises germane, and the boron dopant source comprises borane.

21. The fabrication method according to claim 20, wherein the alkyl-free silane or halogenosilane comprises silicomethane or dichlorosilane.

22. The fabrication method according to claim 20, wherein the third reactive gas further comprises alkyl silane for doping carbon into the doped regions.

23. The fabrication method according to claim 10, wherein the concentration of carbon in the buffer layer is between 0.05% and 1%.
